(19) United States
(12) Patent Application Publication
(10) Pub. No.: US 2012/0166901 A1
(43) Pub. Date: Jun. 28, 2012

(54) INTEGRATED CIRCUIT FOR TESTING SMART CARD AND DRIVING METHOD OF THE CIRCUIT

(75) Inventor: Eui Seung Kim, Hwaseong-si (KR)

(73) Assignee: SAMSUNG ELECTRONICS CO., LTD., Suwon-si (KR)

(21) Appl. No.: 13/242,600

(22) Filed: Sep. 23, 2011

(30) Foreign Application Priority Data
Dec. 27, 2010 (KR) 10-2010-0135202

(51) Int. Cl. G01R 31/3177; G06F 11/25

(52) U.S. Cl. 714/726; 714/E11.155

(57) ABSTRACT

An integrated circuit (IC) is provided. The IC includes a scan controller and a target logic circuit configured to receive a scan input pattern in response to a control of the scan controller, to execute an operation according to the scan input pattern, and to output an execution result. The scan controller compares the execution result with a scan output pattern and outputs a comparison result. The IC can perform a scan test on a particular block that is not controlled by a CPU in a smart card without an additional pad.

### CROSS-REFERENCE TO RELATED APPLICATIONS

This application claims priority under 35 U.S.C. §119 to Korean Patent Application No. 10-2010-0135202 filed on Dec. 27, 2010, the disclosure of which is hereby incorporated by reference in its entirety.

### FIELD

The present inventive concept relates to a test device for a digital circuit, and more particularly, to an integrated circuit for performing a scan test on an internal logic block of a smart card and a method of driving the circuit.

### BACKGROUND

There are many design-for-testability (DFT) methods for the efficient testing of a digital circuit. Among those DFT methods, a scan test is usually used to test a logic circuit. In the scan test, flip-flops in a logic circuit are replaced with scan flip-flops and the scan flip-flops form one or more shift chains. The scan test repeats three steps of shift input, parallel loading, and shift output.

There are two types of scan chains, i.e., a single scan chain and a multi-scan chain. The single scan chain is made by forming all scan flip-flops in a single chain. The multi-scan chain is made by forming all scan flip-flops in multiple chains. The multi-scan chain is usually used to reduce the size of scan test vector.

### SUMMARY

Some embodiments of the present invention provide an integrated circuit (IC) configured to perform a scan test on a particular block that is not controlled by a central processing unit (CPU) in a smart card, without adding a pad and a driving method of the circuit.

According to one aspect of the present invention, there is provided an integrated circuit including a scan controller; and a target logic circuit configured to receive a scan input pattern under control of the scan controller, to execute an operation according to the scan input pattern, and to output an execution result. The scan controller is configured to compare the execution result with a scan output pattern and to output a comparison result.

The integrated circuit may further include an input/output blocker configured to block input/output signals to/from the target logic circuit while the target logic circuit process the scan input pattern during the test operation.

The integrated circuit may further include a central processing unit (CPU) configured to control the scan controller and the input/output blocker during a test operation.

The IC can further comprise a non-volatile memory configured to store the scan input pattern and the scan output pattern in a compressed form. And the CPU can be configured to decompress the scan input pattern and the scan output pattern stored in the non-volatile memory in the compressed form.

The scan controller may be configured to output the comparison result through a single input/output pad. The comparison result may indicate a pass or a fail result of a scan test of the target logic circuit.

The single input/output pad may be pad C7 of a smart card.

The scan controller may be configured to output the comparison result to a tester through the single input/output pad.

The integrated circuit may further include a memory configured to store the scan input pattern and the scan output pattern transmitted from the tester through the single input/output pad.

The integrated circuit may be implemented in a smart card or a smart phone.

According to another aspect of the present invention, there is provided a test operation driving method of an integrated circuit. The driving method includes transmitting a scan input pattern to a target logic circuit that is not controlled by a central processing unit (CPU); the target logic circuit processing the scan input pattern to execute a test; and comparing an execution result with a scan output pattern and generating a comparison result.

The driving method may further include outputting the comparison result through a single input/output pad. The input/output pad may be pad C7 of a smart card.

The smart card may form part of a smart phone.

The comparison result may indicate a pass or a fail result of a scan test of the target logic circuit.

The driving method may further include storing in a non-volatile memory the scan input pattern and the scan output pattern which are transmitted through the single input/output pad.

The driving method may further include blocking input/output signals to/from the target logic circuit while the target logic circuit is processing the scan input pattern during the test operation.

According to further aspects of the present invention, there is provided a driving method of an integrated circuit (IC). The driving method includes decompressing a compressed scan input pattern and a compressed scan output pattern; transmitting a scan input pattern, which has been decompressed, to a target logic circuit; executing an operation according to the scan input pattern; and comparing an execution result with a scan output pattern and outputting a comparison result.

The driving method may further include blocking input/output of the target logic circuit while the target logic circuit is tested using the scan input pattern.

According to another aspect of the invention, provided is an integrated circuit (IC) configured to perform a test operation. The IC comprises an I/O pad; a central processing unit coupled to a memory; a scan controller configured to receive a scan pattern comprising a scan input pattern and a scan output pattern; and a target logic circuit configured to be controlled independently from the CPU, and to receive the scan input pattern from the scan controller, to execute an operation according to the scan input pattern, and to output an execution result. The scan controller is configured to compare the execution result with the scan output pattern and to output a comparison result comprising a pass result when the scan output pattern matches the execution result and a fail result when the scan output pattern does not match the execution result.

The CPU can be configured to send a plurality of scan patterns to the scan controller.

The CPU can also be configured to determine if the scan pattern used in the test operation is a last scan pattern from the plurality of scan patterns.

The target logic circuit can comprise a random number generator.

The IC can further comprise an input/output blocker configured to block input/output signals to/from of the target logic circuit while the target logic circuit processes the scan input pattern during the test operation.

The IC can be implemented in a smart card or a smart phone.

The I/O pad can be a single input/output pad C7 of the smart card. And the scan controller can be configured to output the comparison result to a tester through the pad C7.

The IC can further comprise a non-volatile memory configured to store the scan input pattern and the scan output pattern in a compressed form. The CPU can be configured to decompress the compressed scan input pattern and the compressed scan output pattern stored in the non-volatile memory and to provide the decompressed scan input pattern and the decompressed scan output pattern to the scan controller.

### BRIEF DESCRIPTION OF THE DRAWINGS

The present invention will become more apparent by describing in detail exemplary embodiments in accordance with aspects thereof, with reference to the attached drawings in which:

FIG. 1 is a block diagram of an exemplary embodiment of a test system including a smart card and a tester, according to an aspect of the present invention;

FIG. 2 is a conceptual diagram showing an exemplary embodiment of details of the smart card illustrated in FIG. 1, according to aspects of the present invention;

FIG. 3 is a flowchart of an exemplary embodiment of a method of operations of the smart card illustrated in FIG. 1, according to aspects of the present invention;

FIG. 4 is a block diagram of an exemplary embodiment of a test system including a smart card and a tester, according to another aspect of the present invention;

FIG. 5 is a flowchart of an exemplary embodiment of the operations of the smart card illustrated in FIG. 4, according to aspects of the present invention;

FIG. 6 is a diagram of an exemplary embodiment of a computer system including the smart card illustrated in FIG. 1, according to aspects of the present invention;

FIG. 7 is a diagram of an exemplary embodiment of a computer system including the smart card illustrated in FIG. 1, according to another aspect of the invention;

FIG. 8 is a diagram of an exemplary embodiment of a computer system including the smart card illustrated in FIG. 1, according to still another aspect of the invention; and

FIG. 9 is a diagram of still another example embodiment of a computer system including the smart card illustrated in FIG. 1, according to still another example embodiment.

### DETAILED DESCRIPTION OF THE EMBODIMENTS

The present invention now will be described more fully hereinafter with reference to the accompanying drawings, in which embodiments of the invention are shown. This invention may, however, be embodied in many different forms and should not be construed as limited to the embodiments set forth herein. In the drawings, the size and relative sizes of layers and regions may be exaggerated for clarity. Like numbers refer to like elements throughout.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. As used herein, the term “and/or” includes any and all combinations of one or more of the associated listed items and may be abbreviated as “/”.

It will be understood that, although the terms first, second, etc. may be used herein to describe various elements, these elements should not be limited by these terms. These terms are only used to distinguish one element from another. For example, a first signal could be termed a second signal, and, similarly, a second signal could be termed a first signal without departing from the teachings of the disclosure.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

A smart card, according to some embodiments of the present inventive concept, includes a block or module that is not controlled by a central processing unit (CPU). For instance, the block may include a random number generator. In other words, flip-flops included in the random number generator can be characterized in that they are not be initialized by the CPU. This is because the random number generator functions to prevent secure data from being hacked, e.g., financial information stored in the smart card. Accordingly, an independent solution for testing such a block is required.

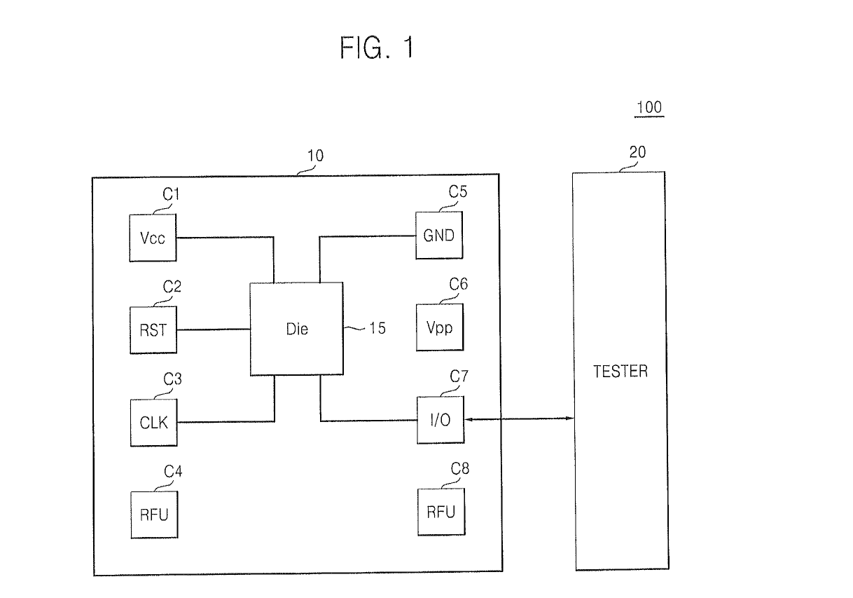

In order to perform a scan test on such a block using a tester, at least four pads are additionally required. Input/output pads for scan-in, scan-out, scan clock, and scan mode signals are essential for to properly perform the scan test. However, the number of input/output pads on the smart card is limited to eight (8) (i.e., C1 through C8 shown in FIG. 1), with five of the eight pads actually used or assigned in the smart card, in this example embodiment. Therefore, it is impossible to perform an independent scan test on the particular block in the smart card using a tester, because the number of available pads is insufficient.

Even if additional input/output pads are provided to connect the tester with the smart card, the drive performance of the input/output pad C7 of the smart card is deteriorated, and therefore, it is actually impossible to transmit scan-test result data to the tester through the input/output pad C7.

To address these problems, various embodiments of the present inventive concept provide a scan controller for use with a smart card. The scan controller is configured to transmit a scan input pattern received from a tester to a target block. The target block carries out an operation according to the scan input pattern under the control of the scan controller and transmits a result of the operation to the scan controller. The scan controller compares the operation result with a scan output pattern and transmits comparison data and/or test pass or fail information to the tester. The tester then indicates or outputs the appropriate test pass or fail result.

As a result, a smart card in accordance with the present inventive concept can test the particular block (e.g., a target block) that is not controlled by the CPU without extra pads added. Technical features in accordance with concepts of the present invention will be described in detail with reference to FIGS. 1 through 3.

FIG. 1 is a block diagram of an embodiment comprising a test system 100 including a smart card 10 and a tester 20 according to aspects of the present invention. Referring to FIG. 1, the test system 100 includes the smart card 10 and the tester 20. The smart card 10 includes eight pads C1 through C8 and a die 15. Table 1 is referred to for assignments of the pads C1 through C8 of the smart card 10.

Table 1 shows standard pads used in the smart card 10.

TABLE 1

| PAD | Function | Description |
|---|---|---|
| C1 | Vcc | Power supply |
| C2 | RST | Reset signal |
| C3 | CLK | Clock signal |
| C4 | RFU | Reserved |
| C5 | GND | Ground voltage supply |
| C6 | Vpp | Not used |
| C7 | I/O | Data transmission |
| C8 | RFU | Reserved |

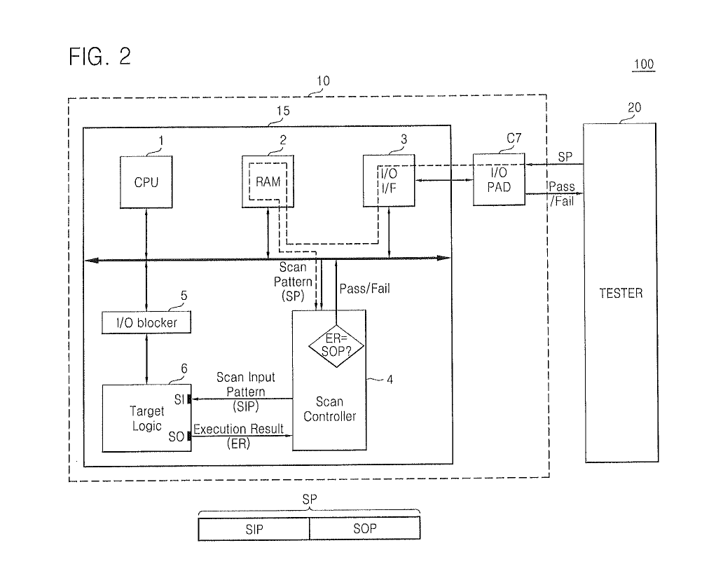

The smart card 10 uses only five pads C1, C2, C3, C5, and C7 among the eight pads C1 through C8 that are provided. In other words, the five pads C1, C2, C3, C5, and C7 are connected to the die 15 and the remaining pads C4, C6, and C8 are not connected to the die 15. The die 15 is a chip cut off from a wafer to make the smart card 10. An embodiment of an internal structure of the smart card 10 or the die 15 will be described in detail with reference to FIG. 2.

FIG. 2 is a detailed diagram of an exemplary embodiment of the smart card 10 illustrated in FIG. 1. For the sake of convenience, the smart card 10 and the tester 20 are illustrated together, but they need not be combined in this way. Referring to FIGS. 1 and 2, the die 15 includes a CPU 1, a random access memory (RAM) 2, an input/output (I/O) interface 3, a scan controller 4, an I/O blocker 5, and a target logic (circuit or block) 6. Also for the sake of convenience, only the I/O pad C7 of the smart card 10 is illustrated in FIG. 2. The other pads are omitted in this figure for simplicity.

The CPU 1 controls the RAM 2 and the I/O interface 3 in a normal operation and controls the scan controller 4 and the I/O blocker 5 in a scan test operation. The RAM 2 stores an operating system (OS) of the smart card 10 or data to be called (or transmitted) to the CPU 1. In addition, the RAM 2 also receives a scan pattern SP from the tester 20 through the I/O pad C7 and stores it, as indicated by the dashed line in FIG. 2. The I/O interface 3 supports an interface with an external device (e.g., the tester 20) of the smart card 10.

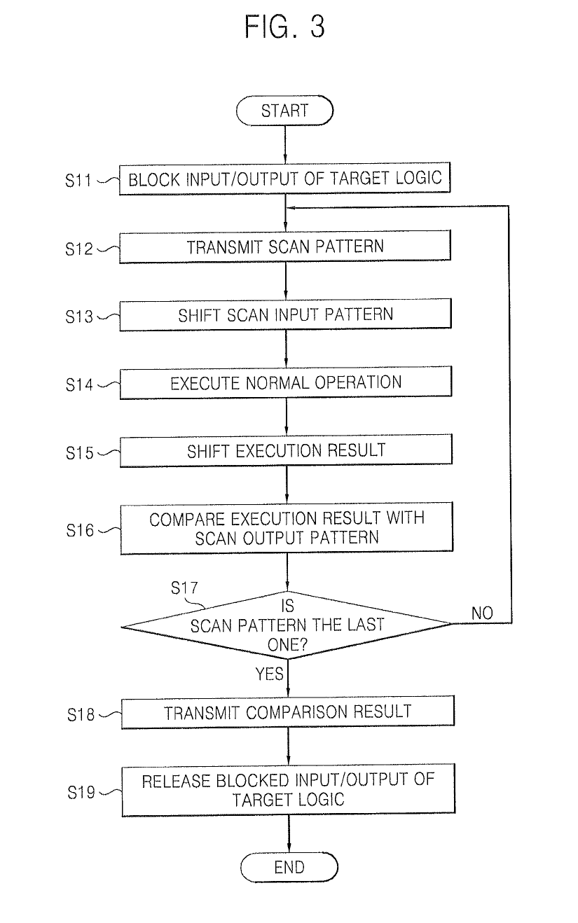

The scan pattern SP includes a scan input pattern SIP and a scan output pattern SOP. The scan controller 4 transmits to the target logic 6 the scan input pattern SIP of the scan pattern SP that was output from the RAM 2. The target logic 6 carries out an operation according to the scan input pattern SIP under the control of the scan controller 4. Details of the operation of the scan controller 4 will be described herein below with reference to FIG. 3.

The I/O blocker 5 is configured to block input/output signals of the target logic 6, while the scan controller 4 performs a scan test on the target logic 6, in order to prevent the CPU 1 from operating in error. The target logic 6 is a logic circuit that is tested independently in the smart card 10. Although the target logic 6 is illustrated to be formed in a single scan chain in the present embodiment, for the sake of convenience, the target logic 6 may be formed in a multi-scan chain in other embodiments. Multi-scan chains are generally known in the art, so not discussed in detail herein.

The scan pattern SP is a test pattern generated by an automatic test pattern generator (ATPG). The ATPG is a tool, i.e., hardware, firmware, software, or some combination thereof, that generates the scan pattern SP for the scan test of the target logic 6. The scan pattern SP includes the scan input pattern SIP and the scan output pattern SOP. The scan input pattern SIP is input to a scan-in pin SI of the target logic 6. The scan output pattern SOP is compared with an execution result ER of the target logic 6 by the scan controller 4. When a comparison result shows that the scan output pattern SOP is the same as the execution result ER, the scan controller 4 outputs a pass signal. Otherwise, the scan controller 4 outputs a failure signal.

In general, in the current embodiments, a low-cost device supporting a clock speed of about 10 MHz is used as the tester 20 for testing the smart card 10. This is because the smart card 10 typically includes a clock that does not have a fast operating clock speed, since there are typically available at a very low cost.

The smart card 10 can include sensitive information, such as financial information, requiring security, and is thus it is important that the smart card 10 be very resistant to hacking. To accomplish this, the smart card 10 uses technology for encrypting information as protection against hacking. For the encryption, the smart card 10 can include a random number generator, which can comprise the target logic 6. The random number generator is configured not to be controlled by the CPU 1 of the smart card 10, as a measure of protection against hacking. The random number generator can, for example, be configured to be initialized by an external attack signal. The random number generator needs an independent test solution, since it is not controlled by the CPU 1. According to the current embodiments, the smart card 10 can perform a scan test on a block, such as the random number generator, which is not controlled by the CPU 1, without a need for an extra pad for the block.

Details of the operation of the scan controller 4 implementing such functions will be described with reference to FIG. 3.

FIG. 3 is a flowchart of exemplary embodiment of details of the operations of the smart card 10 illustrated in FIG. 1, according to aspects of the present invention. Referring to FIGS. 1 through 3, before a scan test operation, the RAM 2 receives the scan pattern SP from the tester 20 through the I/O pad C7 and the I/O interface 3. In the scan test operation, the I/O blocker 5 blocks input/output signals of the target logic 6 according to the control of the CPU 1 in operation S11.

The CPU 1 transmits the scan pattern SP from the RAM 2 to the scan controller 4, in operation S12. The scan controller 4 shifts the scan input pattern SIP in the scan pattern SP to the scan-in pin SI of the target logic 6, in operation S13. In other words, the scan controller 4 transmits the scan input pattern SIP bit-by-bit to the scan-in pin SI of the target logic 6.

The target logic 6 executes a normal operation according to the scan input pattern SIP received during a period of a single clock, in operation S14. The target logic 6 shifts the execution result ER to the scan controller 4 through a scan-out pin SO in response to the control of the scan controller 4, in operation S15. In other words, the target logic 6 transmits the execution result ER bit-by-bit to the scan controller 4 through the scan-out pin SO. The scan controller 4 compares the execution result ER with the scan output pattern SOP, in operation S16. When the execution result ER is the same as the scan output pattern SOP, the scan test is passed; otherwise, the scan test fails.

The CPU 1 determines if the scan pattern SP used in the prior steps is the last scan pattern, in operation S17. When the scan pattern is the last scan pattern, the procedure goes to operation S18. Otherwise, the procedure goes to operation S12. The scan controller 4 transmits a comparison result to the tester 20 through the I/O pad C7 in operation S18. When the comparison result is the same, the scan controller 4 outputs a pass signal to the tester 20; otherwise, the scan controller 4 outputs a failure signal to the tester 20. After the scan test operation is completed, the CPU 1 releases the input/output signal blocking by the blocker 5 in operation S19.

As described above, the scan pattern SP may be received from the external tester 20 and stored in the smart card 10. Since the scan pattern SP includes a lot of repetitions of the same pattern, the compression ratio of the scan pattern will be very high if the scan pattern SP is compressed. Accordingly, it may be more efficient that the smart card 10 stores the scan pattern SP in a compressed form.

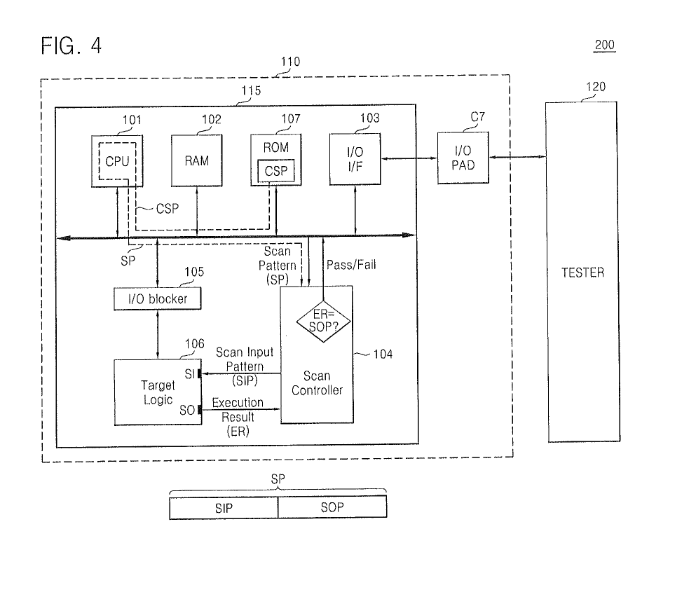

FIG. 4 is a block diagram of an exemplary embodiment of a test system 200 including a smart card 110 and a tester 120, according to still other aspects of the present invention. Referring to FIG. 4, the test system 200 includes the smart card 110 and the tester 120, which is configured to test the smart card 110.

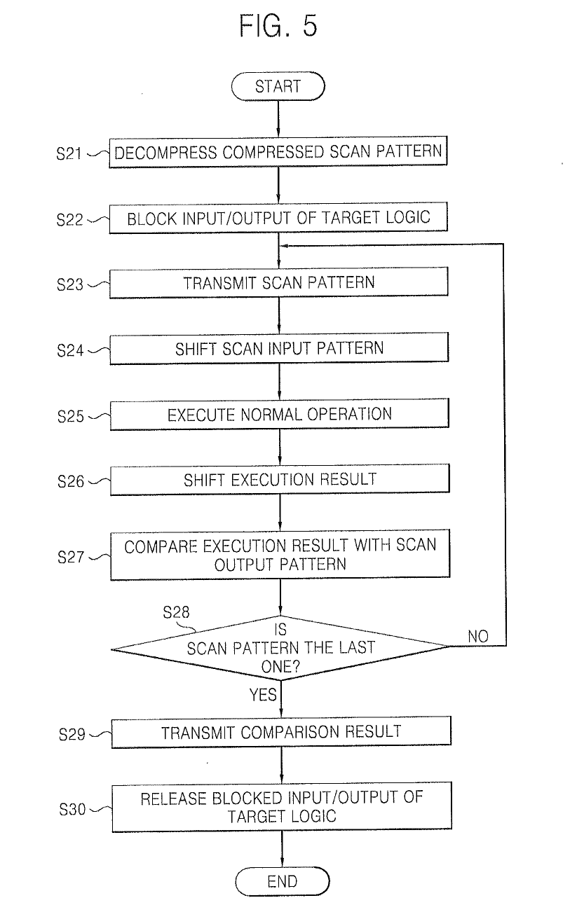

The smart card 110 includes a CPU 101, a RAM 102, an I/O interface 103, a scan controller 104, an I/O blocker 105, and a target logic 106. In addition, the smart card 110 also includes a non-volatile memory, e.g., read-only memory (ROM) 107, which stores a compressed scan pattern CSP. In a scan operation, the CPU 101 decompresses the compressed scan pattern CSP stored in the ROM 107 to generate the scan pattern SP. The scan pattern SP is sent to the scan controller 104, as indicated by the dashed line. The detailed operations of the smart card 110 will be described with reference to FIG. 5.

The smart card 110 illustrated in FIG. 4 is the same as the smart card 10 illustrated in FIG. 2, except for the ROM 107. Thus, redundant description will be omitted.

FIG. 5 is a flowchart of an exemplary embodiment of the operations of the smart card 110 illustrated in FIG. 4, according to aspects of the present invention. Referring to FIGS. 4 and 5, the CPU 101 decompresses the compressed scan pattern CSP stored in the ROM 107 to generate the scan pattern SP, in operation S21. In a scan test operation, the I/O blocker 105 blocks input and/or output of the target logic 106 in response to the control of the CPU 101, in operation S22.

The CPU 101 transmits the scan pattern SP to the scan controller 104, in operation S23. The scan controller 104 shifts the scan input pattern SIP of the scan pattern SP to a scan-in pin SI of the target logic 106, in operation S24.

The target logic 106 executes a normal operation according to the scan input pattern SIP received during a period of a single clock cycle, in operation S25. The target logic 106 shifts an execution result ER to the scan controller 104 through a scan-out pin SO in response to the control of the scan controller 104, in operation S26.

The scan controller 104 compares the execution result ER with the scan output pattern SOP, in operation S27. When the execution result ER is the same as the scan output pattern SOP, the scan test is passed. Otherwise, the scan test fails.

The CPU 101 determines if the scan pattern SP is the last scan pattern, in operation S28. When it is the last scan pattern, the procedure goes to operation S29; otherwise, the procedure goes to operation S23.

The scan controller 104 transmits a comparison result to the tester 120 through the I/O pad C7, in operation S29. When the comparison result is the same, the scan controller 104 outputs a pass signal to the tester 120; otherwise, the scan controller 104 outputs a failure signal to the tester 120. After the scan test operation is completed, the CPU 101 releases the input and/or output blocking by the blocker 105, in operation S30.

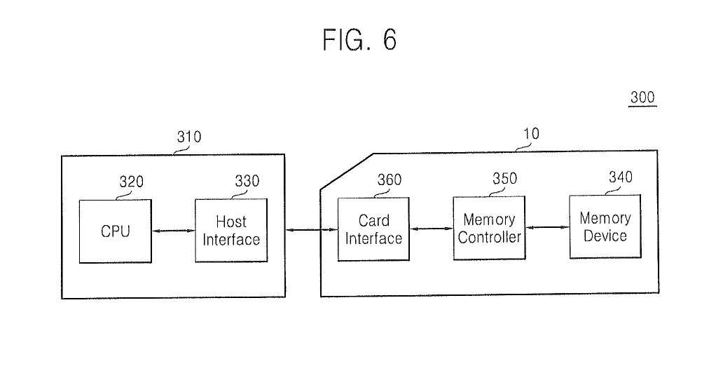

FIG. 6 is a diagram of an exemplary embodiment of a computer system 300 including the smart card 10 illustrated in FIG. 1, according to aspects of the present invention. Referring to FIG. 6, the computer system 300 includes a host computer 310 and a memory card, i.e., the smart card 10. The smart card 10 may be replaced with the smart card 110 illustrated in FIG. 4 in other embodiments.

The host computer 310 includes a CPU 320 and a host interface 330. The smart card 10 includes a memory device 340, a memory controller 350, and a card interface 360, in this embodiment.

The memory controller 350 may control data exchange between the memory device 340 and the card interface 360. In some embodiments, the card interface 360 may be a secure digital (SD) card interface, a multi-media card (MMC) interface, an eMMC™ interface, but the present inventive concept is not restricted to such embodiments.

When the smart card 10 is connected with the host interface 330 of the host computer 310, the card interface 360 may interface the CPU 320 and the memory controller 350 for data exchange according to a protocol of the CPU 320.

In some embodiments, the card interface 360 may support a universal serial bus (USB) protocol or an interchip (IC)-USB protocol. Here, the card interface 360 may indicate hardware supporting a protocol used by the host computer 310, software installed in the hardware, firmware, or other signal transmission technical implementations.

When the smart card 10 is connected with the host interface 330 of the host computer 310, such as a personal computer (PC), a tablet PC, a digital camera, a digital audio player, a cellular phone, a console video game hardware, or a digital set-top box, the host interface 330 may perform data communication with the memory device 340 through the card interface 360 and the memory controller 350 according to the control of the CPU 320.

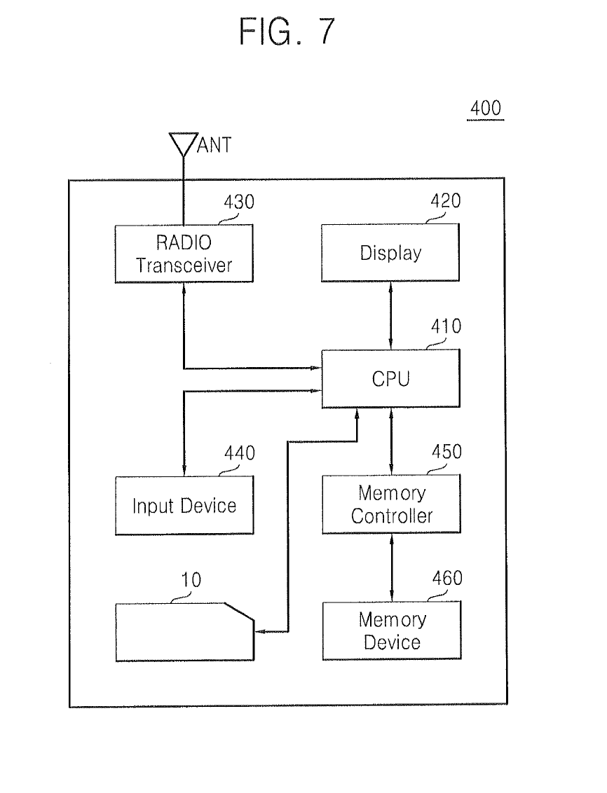

FIG. 7 is a diagram of an exemplary embodiment of a computer system 400 including the smart card 10 illustrated in FIG. 1, according to another aspect of the invention. Referring to FIG. 7, the computer system 400 including the smart card 10 illustrated in FIG. 1 may be implemented in a cellular phone, a smart phone, a personal digital assistant (PDA), or a radio communication system, as examples. Although the present invention is not limited to such embodiments.

The computer system 400 includes a memory device 460 and a memory controller 450 controlling the operations of the memory device 460. The memory controller 450 may control the data access operations, e.g., a write operation, a read operation, a program operation, and an erase operation, of the memory device 460 according to the control of the CPU 410.

Data in the memory device 460 may be displayed through a display 420 according to the control of the CPU 410 and the memory controller 450. The radio transceiver 430 transmits or receives radio signals through an antenna ANT. The radio transceiver 430 may convert radio signals received through the antenna ANT into signals that can be processed by the CPU 410. Accordingly, the CPU 410 may process the signals output from the radio transceiver 430 and transmit the processed signals to the memory controller 450 or the display 420. The memory controller 450 may store the signals processed by the CPU 410 in the memory device 460.

The radio transceiver 430 may also convert signals output from the CPU 410 into radio signals and outputs the radio signals to an external device through the antenna ANT. The input device 440 enables control signals for controlling the operation of the CPU 410 or data to be processed by the CPU 410 to be input to the computer system 400. The input device 440 may be implemented by a pointing device, such as a touch pad or a computer mouse, a keypad, or a keyboard, as examples.

The CPU 410 may control the operation of the display 420 to display data output from the memory controller 450, data output from the radio transceiver 430, or data output from the input device 440.

The memory controller 450, which controls the operations of the memory device 460, may be implemented as a part of the CPU 410 or as a separate chip. In addition, the smart card 10 may be attached to or detached from the computer system 400. The smart card 10 may be replaced with the smart card 110 illustrated in FIG. 4 in other embodiments.

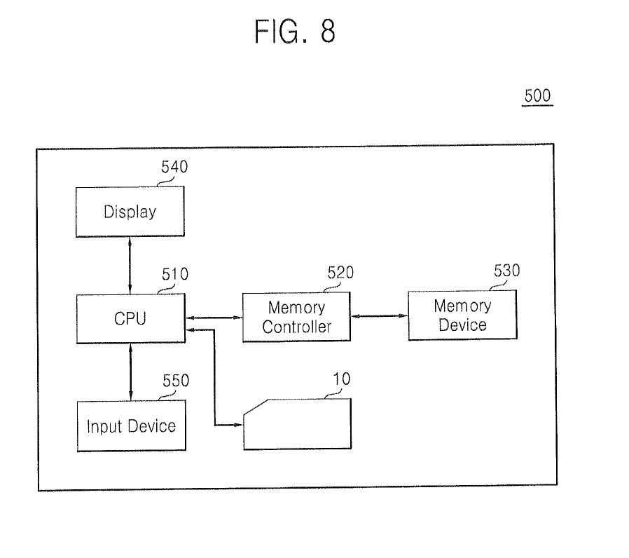

FIG. 8 is a diagram of an exemplary embodiment of a computer system 500 including the smart card 10 illustrated in FIG. 1, according to still another aspect of the invention. Referring to FIG. 8, the computer system 500 including the smart card 10 illustrated in FIG. 1 may be implemented as, or take the form of, a personal computer (PC), a network server, a tablet PC, a netbook, an e-reader, a PDA, a portable multimedia player (PMP), an MP3 player, or an MP4 player, as examples. However, the present invention is not limited to such embodiments.

The computer system 500 includes a CPU 510, a memory device 530, a memory controller 520 controlling the data processing operations of the memory device 530, a display 540, and an input device 550.

The CPU 510 may display data stored in the memory device 530 through the display 540 according to data input through the input device 550. The input device 550 may be implemented by a pointing device, such as a touch pad or a computer mouse, a touch screen, a keypad, or a keyboard, as examples. The CPU 510 may control the overall operation of the computer system 500 and control the operations of the memory controller 520.

The memory controller 520, which may control the operations of the memory device 530, may be implemented as a part of the CPU 510 or as a separate chip. In addition, the smart card 10 may be attached to or detached from the computer system 500. The smart card 10 may be replaced with the smart card 110 illustrated in FIG. 4 in other embodiments.

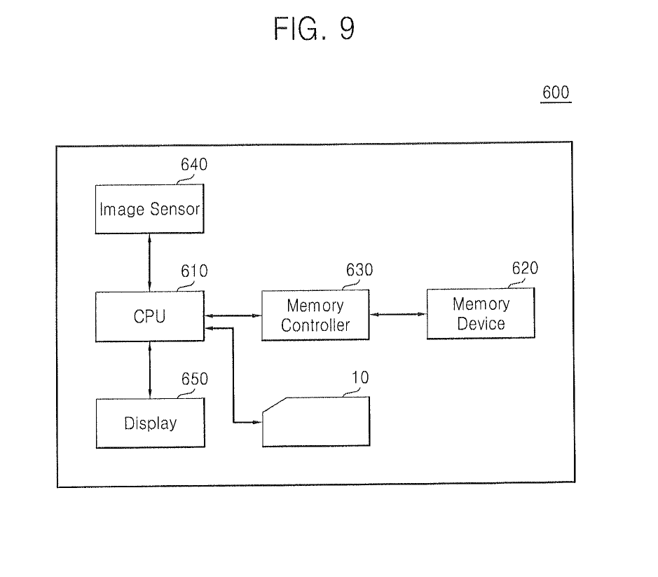

FIG. 9 is a diagram of an exemplary embodiment of a computer system 600 including the smart card 10 illustrated in FIG. 1, according to still another aspect of the present invention. Referring to FIG. 9, the computer system 600 including the smart card 10 illustrated in FIG. 1 may be implemented as an image processing device, like a digital camera or a cellular phone, or smart phone equipped with a digital camera, as examples. However, the present invention is not limited to such embodiments.

The computer system 600 includes a CPU 610, a memory device 620, a memory controller 630 controlling the data processing operations, such as a write operation, a read operation, a program operation, and an erase operation, of the memory device 620. The computer system 600 also includes an image sensor 640 and a display 650.

The image sensor 640 converts optical images into digital signals and outputs the digital signals to the CPU 610 or the memory controller 630. The digital signals may be displayed through the display 650 or stored in the memory device 620 through the memory controller 630 according to the control of the CPU 610. Data stored in the memory device 620 may be displayed through the display 650 according to the control of the CPU 610 or the memory controller 630.

The memory controller 630, which may control the operations of the memory device 620, may be implemented as a part of the CPU 610 or as a separate chip. In addition, the smart card 10 may be attached to or detached from the computer system 600. The smart card 10 may be replaced with the smart card 110 illustrated in FIG. 4 in other embodiments.

According to some embodiments of the present invention, an integrated circuit can perform a scan test on a particular operational block or module that is not controlled by a CPU in a smart card, without one or more additional pads required for the scan test.

While embodiments in accordance with aspects of the present invention have been particularly shown and described with reference to the drawings, it will be understood by those of ordinary skill in the art that various changes in forms and details may be made therein without departing from the spirit and scope of the present invention, as defined by the following claims.

What is claimed is:

1. An integrated circuit (IC) configured to perform a test operation, the IC comprising:
a scan controller; and
a target logic circuit configured to receive a scan input pattern under control of the scan controller, to execute an operation according to the scan input pattern, and to output an execution result,
wherein the scan controller is configured to compare the execution result with a scan output pattern and to output a comparison result.

2. The IC of claim 1, further comprising an input/output blocker configured to block input/output signals to/from of the target logic circuit while the target logic circuit processes the scan input pattern during the test operation.

3. The IC of claim 2, further comprising a central processing unit (CPU) configured to control the scan controller and the input/output blocker during the test operation.

4. The IC of claim 3, further comprising a non-volatile memory configured to store the scan input pattern and the scan output pattern in a compressed form; and
the CPU is configured to decompress the scan input pattern and the scan output pattern stored in the non-volatile memory in the compressed form.

5. The IC of claim 1, wherein the scan controller is configured to output the comparison result through a single input/output pad; and
the comparison result indicates a pass or a failure result of a scan test of the target logic circuit.

6. The IC of claim 5, wherein:
the single input/output pad is a pad C7 of a smart card; and
the scan controller is configured to output the comparison result to a tester through the pad C7.

7. The IC claim 1, wherein the IC is implemented in a smart card or a smart phone.

8. A test operation driving method of an integrated circuit (IC), the driving method comprising:
transmitting a scan input pattern to a target logic circuit that is not controlled by a central processing unit of the IC;
the target logic circuit processing the scan input pattern to execute a test operation; and
comparing an execution result with a scan output pattern and generating a comparison result.

9. The driving method of claim 8, further comprising:
outputting the comparison result through a single input/output pad, wherein the input/output pad is pad C7 of a smart card.

10. The driving method of claim 8, wherein the smart card forms part of a smart phone.

11. The driving method of claim 8, wherein the comparison result indicates a pass or a failure result of a scan test of the target logic circuit.

12. The driving method of claim 8, further comprising:
blocking input/output signals to/from the target logic circuit while the target logic circuit is processing the scan input pattern during the test operation.

13. An integrated circuit (IC) configured to perform a test operation, the IC comprising:
an I/O pad;
a central processing unit coupled to a memory;
a scan controller configured to receive a scan pattern comprising a scan input pattern and a scan output pattern; and
a target logic circuit configured to be controlled independently from the CPU, and to receive the scan input pattern from the scan controller, to execute an operation according to the scan input pattern, and to output an execution result,
wherein the scan controller is configured to compare the execution result with the scan output pattern and to output a comparison result comprising a pass result when the scan output pattern matches the execution result and a fail result when the scan output pattern does not match the execution result.

14. The IC of claim 13, wherein the CPU is configured to send a plurality of scan patterns to the scan controller.

15. The IC of claim 14, wherein the CPU is configured to determine if the scan pattern used in the test operation is a last scan pattern from the plurality of scan patterns.

16. The IC of claim 13, wherein the target logic circuit comprises a random number generator.

17. The IC of claim 13, further comprising:
an input/output blocker configured to block input/output signals to/from of the target logic circuit while the target logic circuit processes the scan input pattern during the test operation.

18. The IC claim 13, wherein the IC is implemented in a smart card or a smart phone.

19. The IC of claim 18, wherein:
the I/O pad is a single input/output pad C7 of the smart card; and
the scan controller is configured to output the comparison result to a tester through the pad C7.

20. The IC of claim 13, further comprising:
a non-volatile memory configured to store the scan input pattern and the scan output pattern in a compressed form, wherein the CPU is configured to decompress the compressed scan input pattern and the compressed scan output pattern stored in the non-volatile memory and to provide the decompressed scan input pattern and the decompressed scan output pattern to the scan controller.
